(19) United States
(12) Patent Application Publication
(10) Pub. No.: US 2016/0268213 A1
(43) Pub. Date: Sep. 15, 2016

(54) On Package Floating Metal/Stiffener Grounding to Mitigate RFI and SI Risks

(71) Applicant: INTEL CORPORATION, Santa Clara, CA (US)

(72) Inventors: Hongjin JIANG, Chandler, AZ (US); Robert STARKSTON, Phoenix, AZ (US); Digvijay A. RAORANE, Chandler, AZ (US); Keith D. JONES, Chandler, AZ (US); Ashish DHALL, Chandler, AZ (US); Omkar G. KARHADE, Chandler, AZ (US); Kedar DHANE, Chandler, AZ (US); Suriyakala RAMALINGAM, Chandler, AZ (US); Li-Sheng WENG, Chandler, AZ (US); Robert F. CHENEY, Chandler, AZ (US); Patrick N. STOVER, Chandler, AZ (US)

(21) Appl. No.: 14/642,316

(22) Filed: Mar. 9, 2015

(51) Int. Cl. H01L 23/552; H01L 23/00

(52) U.S. Cl. CPC H01L 23/552; H01L 24/32; H01L 24/83; H01L 2224/32155; H01L 2224/83851

(57) ABSTRACT

An apparatus including a package including a die and a package substrate, the package substrate including a conductor; and a stiffener body electrically coupled to the conductor of the package substrate. An apparatus including a package including a die and a package substrate; a stiffener body coupled to the package substrate; and an electrically conductive path between the stiffener body and the package substrate. A method including electrically coupling a stiffener body to a conductor of a package substrate.

### BACKGROUND

1. Field

Integrated circuit packaging.

2. Description of Related Art

The use of stiffeners has become common for coreless, ultra thin core client ball grid array (BGA) products for effective package warpage control and reduced variation. Stiffeners having a metal body, however, can act as an antenna and increase radio frequency interference (RFI) risks and signal integrity (SI) risks. Strong RFI can reduce WiFi/WWAN throughput and induce user experience degradation and certification failures. Metal body stiffeners also make central processing unit (CPU) more susceptible to electrostatic discharge (ESD) noise and induce strong signal crosstalk at a stiffener resonant frequency.

Electromagnetic interference (EMI) is a serious issue in modern electronic devices/mobile application. Generally, EMI is a disturbance to the electric field due to either electromagnetic induction or electromagnetic radiation emitted from an external source. While EMI exists across the entire electromagnetic spectrum, from direct current (DC) electricity at less than one hertz (Hz) to gamma rays above 1020 Hz, the great majority of EMI problems are limited to that part of the spectrum between 25 kHz and 10 GHz. This portion is known as the radio frequency interference (RFI) area and covers radio and audio frequencies. The acronym EMI is generally used to represent both EMI and RFI. Radio frequency interference is also described as any undesirable electrical energy with content within the frequency range dedicated to radio frequency transmission. Radiated RFI is most often found in the frequency range from 30 MHz to 10 GHz. These may be transient, continuous or intermittent in occurrence. External sources of EMI could be communication and radar transmitters, electric switch contacts, computers, voltage regulators, pulse generators, arc/vapor lamps, intermittent ground connections, solar noise, lightening electromagnetic pulses. EMI affects the ability of high-performance electronic devices to maintain signal integrity in the time domain and for power integrity in the frequency domain. For integrated circuits, it is generally RF frequency that is the most significant for mobile devices. The electromagnetic radiation generated by one electronic RF device may negatively affect other, similar, electronic devices such as cell phones, radios. For example, when a mobile phone is ON, a great deal of power is transmitted. The device interferes with RF frequencies of other devices. EMI/RFI Shielding is necessary in telecomm because radio transmissions can hamper a reception of a signal by a recipient if the signals are near the same frequency. EMI/RFI shielding may prevent incorrect frequencies from interfering with a device. In medical hospital, equipment must meet standards set by the Food and Drug Administration (FDA) to prevent machinery from being affected by cell phones, personal digital assistants (PDAs), or other electronic devices. EMI/RFI shielding helps to make such protections possible. For mobile devices, printed circuit board (PCB) size has been constantly decreasing, power density has been increasing, and power consumption has been reducing; all of which demands low EMI.

### BRIEF DESCRIPTION OF THE DRAWINGS

FIG. 1 shows a cross-sectional side view of a portion of an assembly including integrated circuit package and stiffener.

FIG. 2 shows a top view of the assembly of FIG. 1.

FIG. 3 shows a cross-sectional side view of another embodiment of a package assembly.

FIG. 4 shows a cross-sectional side view of another embodiment of a package assembly.

FIG. 5 shows a cross-sectional side view of another embodiment of a package assembly.

FIG. 6 shows a cross-sectional side view of another embodiment of a package assembly.

FIG. 7 shows a cross-sectional side view of another embodiment of a package assembly.

FIG. 8 shows a cross-sectional side view of another embodiment of a package assembly.

FIG. 9 shows a cross-sectional side view of another embodiment of a package assembly.

FIG. 10 shows a flow chart of forming a package assembly such as a package assembly illustrated in FIG. 9.

FIG. 11 shows a cross-sectional side view of a portion of a sacrificial material or core substrate having copper foil formed thereon as part of a panel preparation process.

FIG. 12 shows the structure of FIG. 11 following the introduction of a sacrificial copper foil on opposing sides of the structure.

FIG. 13 shows the structure of FIG. 12 following the formation of carrier build-up layers on opposing sides of the structure.

FIG. 14 shows the structure of FIG. 13 following the separation of a build-up package substrate from the sacrificial substrate and the attachment of a stiffener and a die to the package substrate.

FIG. 15 shows the structure of FIG. 14 following introducing of a conductive layer shield on the stiffener and package substrate.

FIG. 16 illustrates an embodiment of a computing device.

### DETAILED DESCRIPTION

Stiffener grounding solutions to mitigate RFI and SI risks in integrated circuit packages are disclosed. In one embodiment, an apparatus including a package is disclosed that includes a die and a package substrate and a stiffener body electrically connected to a conductor of the package substrate. In another embodiment, an apparatus is disclosed that includes a package including a die and a package substrate, a stiffener body coupled to the package substrate and an electrically path between the stiffener body and the package substrate. A conductive path (e.g., a ground path) between a stiffener body and a package substrate can be achieved through conductive adhesives, solder paste materials, stiffener modifications or a conductive material connected to each component.

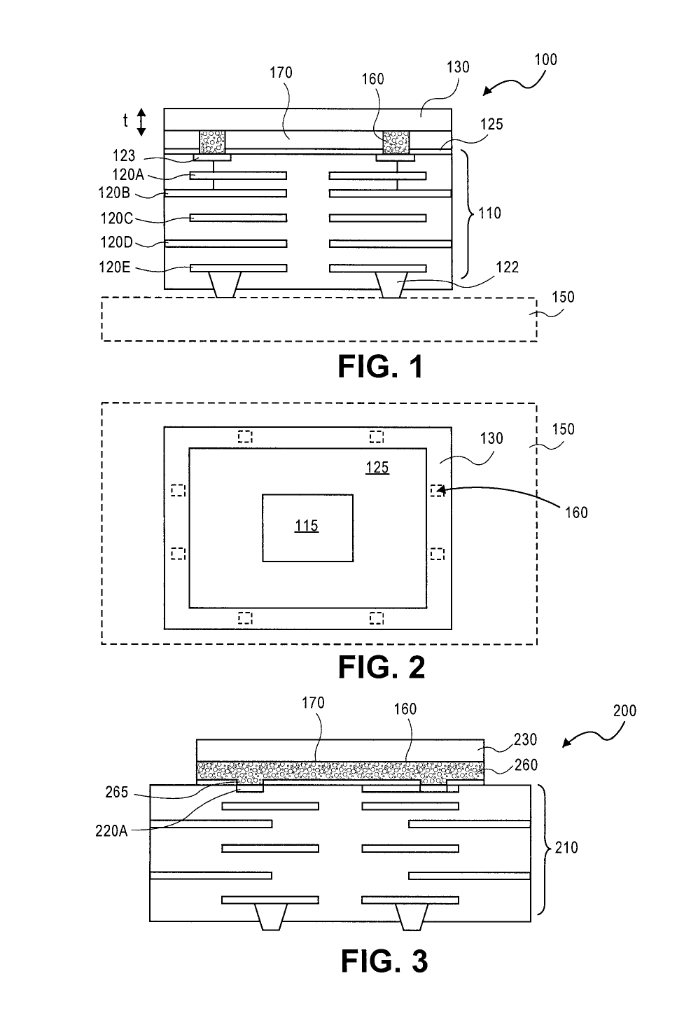

FIG. 1 shows a cross-sectional side view of a portion of an assembly including an integrated circuit package and a stiffener. FIG. 2 shows a top view of the assembly of FIG. 1. Assembly 100 includes package substrate 110, die 115 connected to package substrate 110 and stiffener 120 connected to the package substrate and surrounding die 115. In this embodiment, stiffener 120 is a continuous structure. In another embodiment, stiffener 120 is not continuous. Representatively, package substrate 110 is a coreless or an ultra-thin core (UTC) package. UTC packages typically include a 100 microns (μm) to 200 μm thick core with build-up layers similar to cored substrates. The core is made up of pre-peg material, inner copper (Cu) foil and outer copper foil. In vacuum based architecture, inner and outer copper foils are in contact due to vacuum created between them. In adhesive based architectures, the inner and outer copper (Cu) foils are held together by a low peel strength grade adhesive between them. Core material (pre-preg) adheres to inner and outer copper foil. In order to get a coreless package, build-up layers are built on both sides of the core. Build-up layers are constructed by laminating, curing, drilling and desmearing ABF layer followed by self-aligned plating (SAP) process to form conductive layers or lines and conductive vias. After all build-up layers are laminated, the panel is routed and the outer copper foil is separated from the inner copper foil, and the core is removed. Exposed outer copper foil is etched and the etch stop material is then removed. Thus, the final package consists of only build-up layers. In case of a coreless package, the package substrate is ready to get attached to a CPU/PCH die via a flip chip process. UTC/coreless package is targeted for low Z height products such as mobile chips/devices.

Referring to FIG. 1, package substrate 110 of assembly 100 includes a number of layers of conductive metal lines or layers including conductive layer 120A, conductive layer 120B, conductive layer 120C, conductive layer 120D and conductive layer 120E. Each conductive layer is separated from a subsequent conductive layer via dielectric material (e.g., an ABF film or sheet). In this embodiment, conductive layer 120A represents an initial conductive layer with the other layers sequentially spaced from the initial layer (conductive layer 120A) in the order of conductive layer 120B, conductive layer 120C, conductive layer 120D followed by ultimate conductive layer 120E, that is furthest from die 115 (furtherest from a die side of package substrate 110). FIG. 1 also shows contact pads 123 positioned above conductive layer 120A (between conductive layer 120 and a top side of the package substrate as viewed). In one embodiment, contact pads 123 are connected through conductive vias to at least one of the conductive layers (e.g., conductive layer 120B) that, in one embodiment, serves as a ground plane. As illustrated, the contact pads need not be connected to initial conductive layer 120A. Finally, FIG. 1 shows contact points 122 on a substrate side of package substrate 110 connected to conductive layer 120E to electrically connect assembly 100 to substrate 150, such as a motherboard.

Disposed on contact pads 123 of package substrate 110 is dielectric layer 125 of, for example, a solder resist. FIG. 1 shows openings through the solder resist to allow contact between contact pads 123 and a body of stiffener 130. In one embodiment, the openings contain isotropic conductive adhesive 160. In the cross-section view of FIG. 1, conductive pathways created by the connection of isotropic conductive adhesive 160 between stiffener 130 and contact pads 123 are shown. The number of pathways, in one embodiment, is determined based on product performance requirements. Isotropic conductive adhesive 160 can be dispensed or printed on to the conductive layer (e.g., a pad area of the conductive layer). FIG. 1 also shows adhesive 170 disposed or positioned between package substrate 110 and stiffener 130 in areas other than where the conductive pathways are formed. In one embodiment, adhesive 170 is a non-conductive adhesive such as silicone or epoxy type of adhesive. In one embodiment, once introduced and deposited each of conductive adhesive 160 and adhesive 170 are cured.

FIG. 3 shows a cross-sectional side view of another embodiment of a package assembly. Package assembly 200 includes package substrate 210 and stiffener 230. As illustrated, similar to the embodiments described with reference to FIG. 1 and FIG. 2, openings are made in certain areas of dielectric material to contact point 223 and a conductive adhesive such as an isotropic conductive adhesive 260 is introduced between stiffener 230 and package substrate 210 and forms a conductive path to an entire underside surface of stiffener 230 as viewed and a conductive layer of the package substrate that representatively serves as a ground layer. In this embodiment, the conductive adhesive is shown as continuous in the sense that adhesive is present, is used to connect stiffener 230 to the package substrate in areas other than where there are openings to an underlying conductive pad of the package. In another embodiment, the conductive adhesive is not continuous in the sense that, excluding areas where there are openings to an underlying conductive pad, there may be areas between stiffener 230 and package substrate 110 with adhesive and other areas without adhesive.

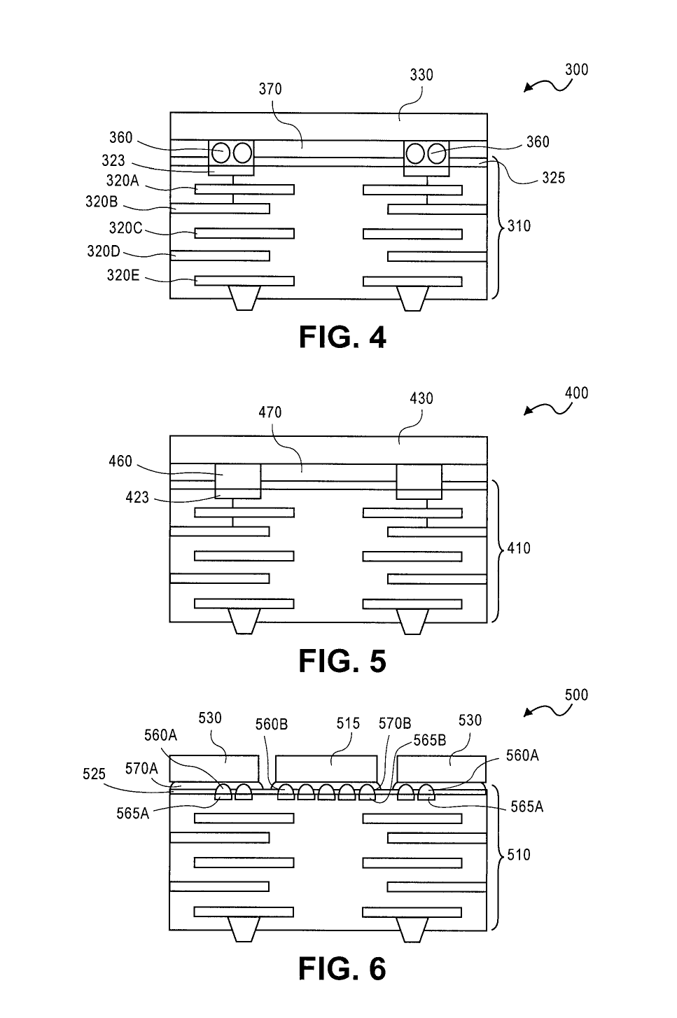

FIG. 4 shows the cross-sectional side view of another embodiment of a package assembly. Package assembly 300, in this embodiment, includes package substrate 310 and stiffener 330 connected thereto. Package substrate 310 includes a number of conductive layers therein including, in a sequential order from a device side of the package substrate, initial conductive layer 320A, conductive layer 320B, conductive layer 320C, conductive layer 320D and ultimate conductive layer 320E. In the illustrated embodiment, contact pads 323 are formed between stiffener 330 and package substrate 310 and such pads are connected through conductive vias to one or more of the conductive layers. In the embodiment, dielectric 325 of a solder resist is disposed on the package substrate and openings are formed through dielectric layer 325 to contact pads 323. A conductive adhesive is disposed or formed between a body of the stiffener and contact pads 323. FIG. 4 shows, in this embodiment, anisotropic conductive adhesive 360 disposed to contact pads 323 and also connected to a base of stiffener 330. An anisotropic conductive adhesive can be dispensed or printed on to such pads as illustrated and then non-conductive adhesive 370 such as a silicon adhesive may be dispensed in the non-pad areas. The adhesives may be cured, for example, under high pressure. In one embodiment, an anisotropic conductive adhesive such as adhesive 360 may include fillers. A representative example of a filler is a conductive material-coated (e.g., metal-coated) elastomeric ball (e.g., gold or silver or silver/gold coated balls) or similar shaped materials that are compressible under stiffener bonding pressure. Fillers such as elastomeric balls can provide improved process tolerance to variations and potentially better contact in electrical performance in addition to providing a conductive pad between the stiffener and the package substrate. In another embodiment, the filler is a gold, silver or silver/gold coated copper ball.

FIG. 5 shows another embodiment of a package assembly including package substrate 410 and stiffener 430. In this embodiment, stiffener 430 is electrically connected to package substrate 410 through a low temperature solder (LTS) solder 460. In one embodiment, LTS paste 460 can be printed onto contact pads 423 of the package substrate, such contact pad electrically connected to a conductive layer or line (e.g., a ground line). FIG. 5 also shows non-conductive adhesive 470 between stiffener 430 and package substrate 410 in areas not including the contact pads. Representatively, during a stiffener bonding process, LTS solder 460 melts and wets to stiffener 430 while the non-conductive adhesive is cured. In one embodiment, a surface of stiffener 430 may include a coating for easier wetting. LTS solder 460 as a conductive material provides a conductive path between stiffener 430 and package substrate 410.

FIG. 6 shows a cross-sectional side view of another embodiment of a package assembly. Assembly 500 includes package substrate 510, chip or die 515 connected to the package substrate and stiffener 530 also connected to the substrate. In this embodiment, die 515 and stiffener 530 are electrically connected to package substrate 510 through micro balls (e.g., solder balls). Representatively, stiffener 530 can be electrically connected to package substrate 510 (e.g., grounded) through connection to conductive contact pads 565A that are connected to a conductive line or lines (e.g., a ground line) of package substrate 510. Contact pads 565A are exposed through dielectric layer 525. FIG. 6 shows conductive micro balls 560A between stiffener 530 and the package substrate connected to conductive pads 565A of the package substrate. FIG. 6 also shows micro balls 560B electrically connecting die 515 to package substrate 510 to contact pads 565B of package substrate 510. High temperature solder can be used for micro balls 565A and micro balls 560B. In one embodiment, micro balls 560A of a solder material is used to attach stiffener 530 prior to attachment of die 515 to package substrate 510 so that a die attach reflow does not melt the stiffener bumps. In another embodiment, adhesives may be utilized to secure stiffener 530 during reflow. In an alternative embodiment, die 515 is attached to package substrate 510 prior to the attachment of stiffener 530. Representatively, die 515 is attached and secured with underfill material 570B. Stiffener 530 is then attached to package substrate 510 followed by underfill material 570A. In this process, micro balls 560A of solder have a similar or lower melting temperature than a solder material of micro balls 560B. In one embodiment, a surface of stiffener 530 is modified (e.g., surface topology change, fluxing, plating with another metal, etc.) for easy wetting. Micro balls 560A between stiffener 530 and package substrate 510 provide connected pad between the structures.

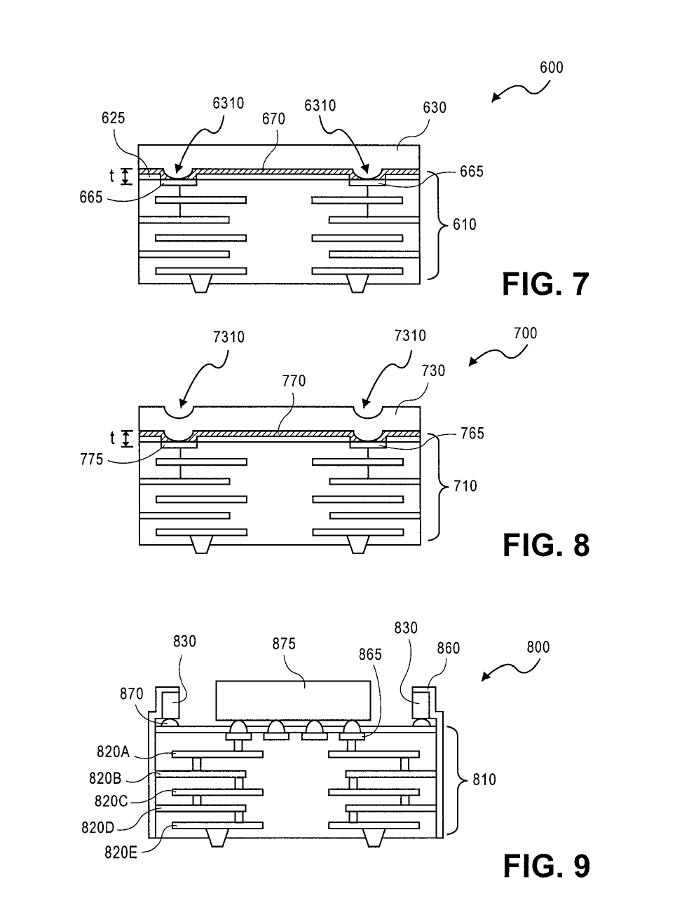

FIG. 7 shows another embodiment of a package assembly. Package assembly 600 includes package substrate 610 and stiffener 630. In this embodiment, stiffener 630 is created with dimples or protrusions 6310 from a surface. These dimples are aligned with locations of conductive pads 665 of a package substrate. In one embodiment, a protrusion thickness, t, of dimples 6310 is equal or larger than a dielectric layer thickness between a surface of a pad and a superior surface of a package substrate (dielectric layer 625) as viewed plus a thickness of any desired adhesive 670 between stiffener 630 and package substrate 610. In one embodiment, adhesive 670 such as a silica adhesive (e.g., a non-conductive adhesive) is dispensed or printed onto an area of a superior surface of package substrate 610 extruding onto areas including conductive pads 665 and then stiffener 630 is attached and the adhesive cured during stiffener bonding process. A conductive pad is generated between stiffener 630 and package substrate 610 through dimples 6310.

FIG. 8 shows another embodiment of a package assembly. Package assembly 700 includes package substrate 710 and stiffener 730. In this embodiment, stiffener 730 has a number of contact tabs providing a protruding or dimpled surface in areas corresponding to contact pads of package substrate 710. In one embodiment, a contact tab thickness, t, is larger than a thickness of dielectric material over or on contact pad 765 (as viewed) and an adhesive (adhesive 770) between stiffener 730 and the package substrate. In one embodiment, contact tabs 7310 are compressible during stiffener bonding process. A conductive pad is generated between stiffener 730 and package substrate 710 through contact tabs 7310.

In another embodiment, in addition to an assembly including a stiffener electrically connected to a package substrate, such as to a ground plane, to form a conductive path between the stiffener and the package substrate, the assembly is also shielded from, for example, EMI/RFI. FIG. 9 shows a cross-sectional side view of another embodiment of a package assembly. Package assembly 800 includes package substrate 810 with integrated circuit die 875 connected to contact pads 865 of the package substrate on a device side of the package substrate and stiffener 830 connected to the device side of the package substrate through adhesive 870 such as a non-conductive adhesive. Package substrate 810 is, for example, a conventional package substrate or an ultra thin core substrate that includes a number of conductive layers in different planes of the substrate and separated from adjacent layers by dielectric material. FIG. 9 illustrates conductive layer 820A, conductive layer 820B, conductive layer 820C, conductive layer 820D and conductive layer 820E. In this embodiment, conductive layer 820A is an initial layer in the sense that it is disposed closest to a device side of the package substrate and to contact pad 865. Conductive layer 820E is an ultimate layer in the sense that it is in a plane furthest from a device side of the package substrate and, in this embodiment, includes contact points for connection of a package substrate to another substrate such as a printed circuit board.

Package assembly 800 illustrated in FIG. 9 also includes conductive layer 860 coating stiffener 830 and disposed on opposing sidewalls of package substrate 810 (e.g., to one or both pairs of opposing sidewalls of a rectilinear package structure). In one embodiment, conductive layer 860 includes a metal material such as copper, nickel or titanium that exhibits high shielding efficiency such that the conductive layer can serve as an EMI/RFI shield. In one embodiment, in addition acting as an EMI/RFI shield, metal layer 860 serves as a conductive path between stiffener 830 and package substrate 810. FIG. 9 shows conductive layers 820B and 820D of package substrate extending to opposing sidewalls of the package substrate. In one embodiment, one or both layers are exposed on one or both a respective sidewalls and therefore physically and electrically connect with conductive layer 860 formed on the sidewall. In one embodiment, one or both of conductive layers 820B and 820D serves as a ground plane. Accordingly, the connection with stiffener 830 by conductive layer 860 provides a conductive path to the package in the ground.

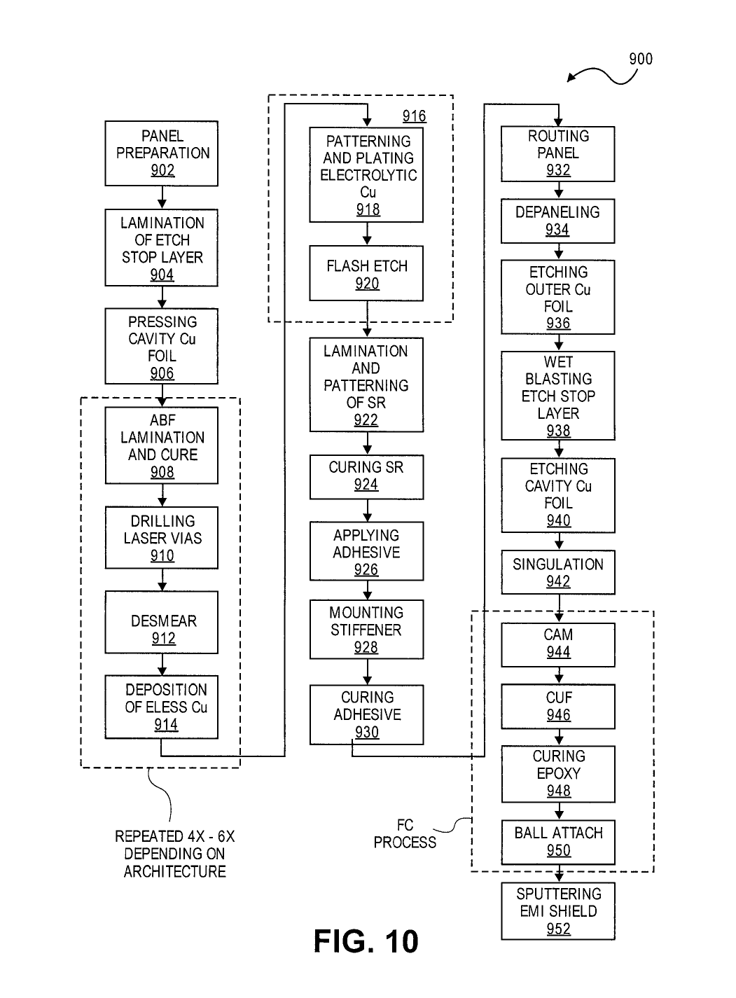

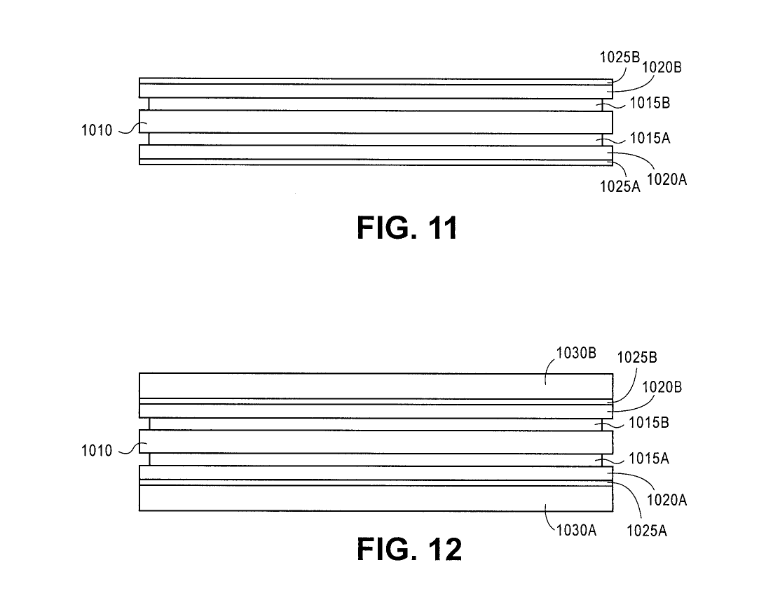

FIG. 10 shows a flow chart for forming a package assembly such as package assembly 800 illustrated in FIG. 9. FIGS. 11-16 illustrate portions of the process described in FIG. 10 in more detail. In the following paragraphs describing FIGS. 11-15, reference will be made to method 900 of FIG. 10.

In one embodiment, the method of process begins with panel preparation (block 902). FIG. 11 shows a cross-sectional side view of a portion of a sacrificial material or core substrate having copper foil formed thereon as part of a panel preparation process (block 902, FIG. 10). FIG. 11 shows substrate 1010 of, for example, a pre-peg material. On opposing sides of substrate 1010 is inner copper foil 1015A and inner copper foil 1015B, respectively. Overlying each inner copper foil is outer copper foil 1020A and outer copper foil 1020B, respectively. In one embodiment, the copper foils are pressed or glued together to form a panel. For vacuum architecture, in one embodiment, inner copper foil 1015A/1015B is shorter than outer copper foil 1020A/1020B so that the prepreg material can adhere to inner copper foil and outer copper foil 1020A/1020B and hence, hold them together. In the embodiment shown in FIG. 11, the panel preparation also includes the introduction of etch stop layers 1025A and 1025B on outer copper foil 1020A and outer copper foil 2010B, respectively. A representative material for etch stop layer 1025A and etch stop layer 1025B is a polymer or dielectric build up layer that is resistant to a copper etch chemistry.

FIG. 12 shows the structure of FIG. 11 following the introduction of a sacrificial copper foil on opposing sides of the structure. Representatively, sacrificial copper foil 1030A and sacrificial copper foil 1030B are pressed on to the structure (block 906, FIG. 10). Representatively, each sacrificial copper foil has a thickness approximating a thickness of a die.

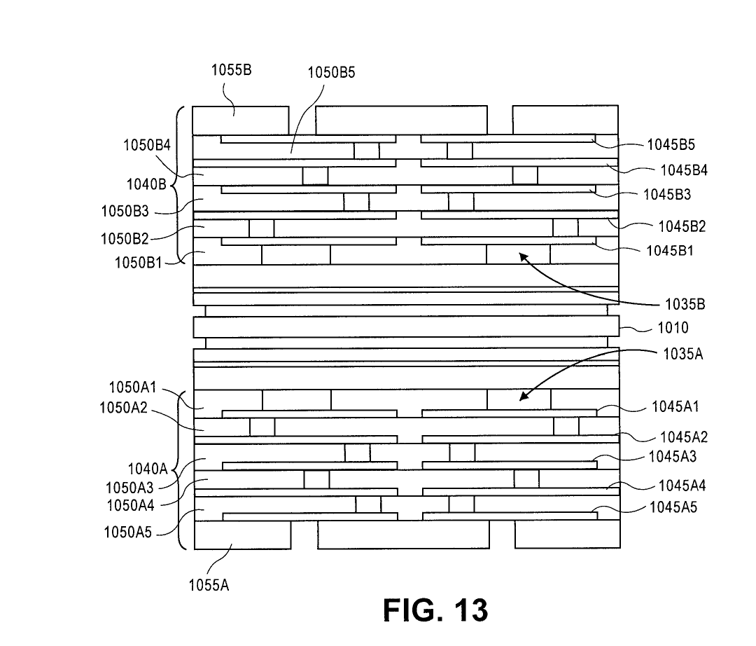

FIG. 13 shows the structure of FIG. 12 following the formation of a build-up carrier build-up layers on opposing sides of the structure. FIG. 13 shows build-up carrier 1040A of alternating layers of patterned conductive material and insulating material on sacrificial copper panel 1030A and build-up carrier 1040B of alternating layers of patterned conductive material and insulating material on sacrificial copper panel 1030B. A process of forming build-up layers will be described with reference to build-up carrier 1040A. Representatively, initially, a layer of dielectric material 1050A1 is introduced on sacrificial copper panel 1030A. In one embodiment, dielectric material 1050A1 is a dielectric build-up layer material that is a film or sheet of, for example, ABF material that is laminated to copper panel 1030A (block 908, FIG. 10). Following the introduction of dielectric material 1030A, openings are formed through dielectric material 1050A1 in areas where it is desired for contacts between the package substrate and another substrate (e.g., a motherboard). One way to form openings is through a laser drilling process (block 910, FIG. 10). Following forming the openings or vias through dielectric material 1050A1, the vias are desmeared (block 912, FIG. 10). An electroless copper material may then be introduced/deposited in the vias and on a surface of dielectric material 1050A1 (block 914, FIG. 10). A pattern mask may then be introduced on the surface of dielectric material 1050A1 including the electroless copper material. The patterning defines a trace routing for a first conductive level or layer through, for example, openings in the mask. Electrolytic copper is then plated on the exposed electroless copper on dielectric material 1050A1 and in the vias (block 916, FIG. 10). Following electrolytic copper plating, a mask used to define the pattern (e.g., a DFR mask) is removed by, for example, stripping to leave copper traces (conductive material). A flash etch is then carried out to remove the exposed electroless copper between the formed traces (block 920, FIG. 10).

The above processes associated with introducing a dielectric material and a patterned conductive layer may optionally be repeated one or more times until a desired number of build-up layers are formed. FIG. 13 shows build-up carrier 1040A including as an example conductive layers 1045A1, 1045A2, 1045A3, 1045A4 and 1045A5 disposed between dielectric materials 1050A1, 1050A2, 1050A3, 1050A4 and 1050A5. Following the patterning of the last or ultimate conductive material layer (conductive layer 1045A5/1045B2), a final dielectric material of, for example, solder resist may be introduced (block 922, FIG. 10). FIG. 13 shows dielectric layer 1055A of, for example, a laminated solder resist film introduced on patterned conductive layer 1045A5 and dielectric layer 1055B of a similar material introduced on patterned conductive layer 1045B5. FIG. 13 also shows patterning of dielectric layer 1055A to form openings to conductive layer 1045A5 for, for example, solder connections to the panel. Dielectric layer 1055B is similarly patterned. Following the introduction and patterning of dielectric layer 1055A/1055B of, for example, a solder resist, the dielectric layer may be cured (block 924, FIG. 10).

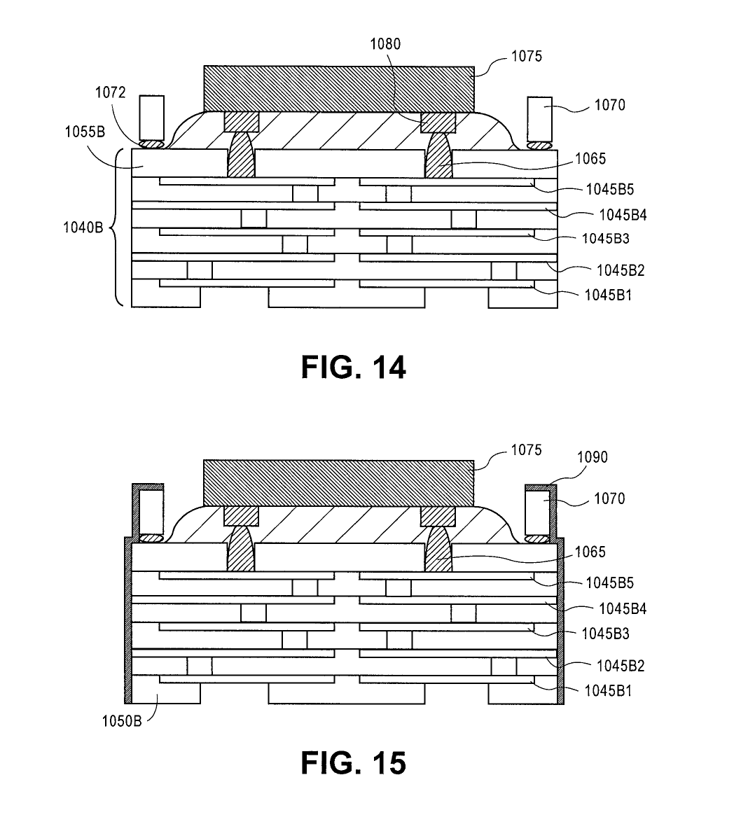

FIG. 14 shows the structure of FIG. 13 following the separation of a build-up package substrate from the sacrificial substrate and the attachment of a stiffener to the package substrate and illustrates routing of the structure. As illustrated in FIG. 14, both sides of substrate 1010 include build-up packaging layers. In order to separate a package substrate or panel from substrate 1010 and associated copper foils (copper foils 1015A/1015B, 1020A/1020B), in one embodiment, the structure is routed along its perimeter on all four sides of the panel (block 932, FIG. 10). Routing may be accomplished with, for example, a Hitachi router. The routing removes any adhesive that holds the inner copper foils 1015A/1015B and outer copper foils 1020A/1020B and substrate 1010 together. In such manner, inner copper foils 1015A/1015B get detached from outer copper foils 1020A/1020B (block 934, FIG. 10). FIG. 14 shows the separated structure focusing on substrate 1040B.

Following the separation, outer copper foils 1020A and 1020B are removed from each separated panel or package (block 936, FIG. 10). One way a copper foil may be removed is by an etching process. FIG. 14 shows the structure after outer copper foil 1020B is removed. A suitable etching technique to remove the copper panel is a wet chemical etchant.

Once outer copper foil 1020B, etch stop layer 1025B is removed. In one embodiment, etch stop layer 1025B (see FIG. 11) may be removed by exposing the layer to a wet blaster (block 938, FIG. 10). A wet blaster process provides selectivity in removing the etch stop layer while leaving the sacrificial copper foil 1030B.

Following the removal of etch stop layer 1025B, in one embodiment, sacrificial copper foil 1030B is removed. One technique for removing sacrificial copper foil 1030B is by an etching process using a chemical solution similar to etching the outer copper foil as described above (block 940, FIG. 10). FIG. 14 shows the structure following the removal of the sacrificial copper foil.

The above process may be formed on a large substrate such that multiple panels or packages may be formed simultaneously on each side of, for example, substrate 1010. Following the removal of sacrificial copper foil 1030B, the structure may be singulated into individual units (block 942, FIG. 10). One singulation process is a sawing or cutting process.

In one embodiment, once the package or panel is singulated, a stiffener is attached to the package substrate or panel. In another embodiment, a stiffener may be attached to the package substrate or panel prior to separation of the package substrate or panel from substrate 1010 and/or prior to singulation. FIG. 14 shows stiffener 1070 connected/attached to the package substrate by adhesive 1072 between dielectric layer 1055B and stiffener 1070 (block 928, FIG. 10). In one embodiment, stiffener 1070 is a metal material such as copper or stainless steel in the shape of a frame with representative dimensions of a width of 1 millimeter (mm) to 5 mms and a thickness of 0.1 mm to 0.5 mm. In another embodiment, stiffener 1070 is or includes an non-conductive material. A suitable adhesive to connect/attach stiffener 1070 to dielectric layer 1055B of a solder resist is representatively an epoxy or silicone or similar material (block 930, FIG. 10). The epoxy is introduced in a liquid form and following connection/attachment of stiffener 1070, the epoxy is cured such as by exposing the structure to a heat source (block 930, FIG. 10).

FIG. 14 also shows the structure following the attachment of a chip or die to the package substrate (block 944, FIG. 10). The die attach may precede or follow the stiffener attach described above. Representatively, solder material 1065 (e.g., solder balls) are introduced in patterned openings of dielectric layer 1055B on a die side of the package substrate in areas corresponding to contact points of pads (e.g., pillars 1080) associated with die 1075. As illustrated in this embodiment, solder material contacts conductive layer 1045B5. Die 1075 is then connected/attached to the package substrate through solder material connections. Once connected, the structure is subjected to a reflow process. Following the die attach process, an underfill material of, for example a dielectric material may be introduced between the die and the package substrate (block 948, FIG. 10).

FIG. 15 shows the structure of FIG. 14 following the connection/attachment of solder material (solder balls) on a substrate side of the package substrate and after introducing a conductive layer shield on the stiffener and package substrate. FIG. 15 shows solder material 1095 (e.g., solder balls) introduced in openings of dielectric layer or film 1050B1 (block 950, FIG. 10). As illustrated, solder material 1095 is introduced to conductive layer 1045B1.

FIG. 15 shows the structure of FIG. 14 following the coating of shield material 1090 on stiffener 1070 and the package substrate. In one embodiment, a shield layer is a conductive material such as a metal that may be introduced by, for example, a sputtering process to coat the metal on the package. Representatively, an individual package may be placed in a vacuum chamber along with a target metal for a sputtering process. A plasma is introduced into the vacuum chamber. The plasma strikes the metal target. The metal target is then bombarded by energetic particles from the plasma. Liberated atoms from the target metal are deposited on the package along the line of site. Representatively, an argon plasma is used. Suitable metals for an interference shield (e.g., EMI and/or RFI shield) include, but are not limited to, nickel and copper. In another embodiment, multiple metals may be used, such as layers of nickel and copper. In one embodiment, a total thickness of a metal layer, or a metal stack consisting of different metals with the same or different thicknesses is less than about six microns and, in another embodiment, less than about three microns.

The method described with reference to the flow chart of FIG. 10 and the illustrations of FIGS. 11-16 are representatives of a method to form a EMI/RFI shielded package including a stiffener wherein a package substrate is a coreless or UTC package substrate. In another embodiment, where the package substrate is a conventional package substrate, a method to form an EMI/RFI shield may proceed as described with respect to block 944 through block 952 of the flow chart of FIG. 10.

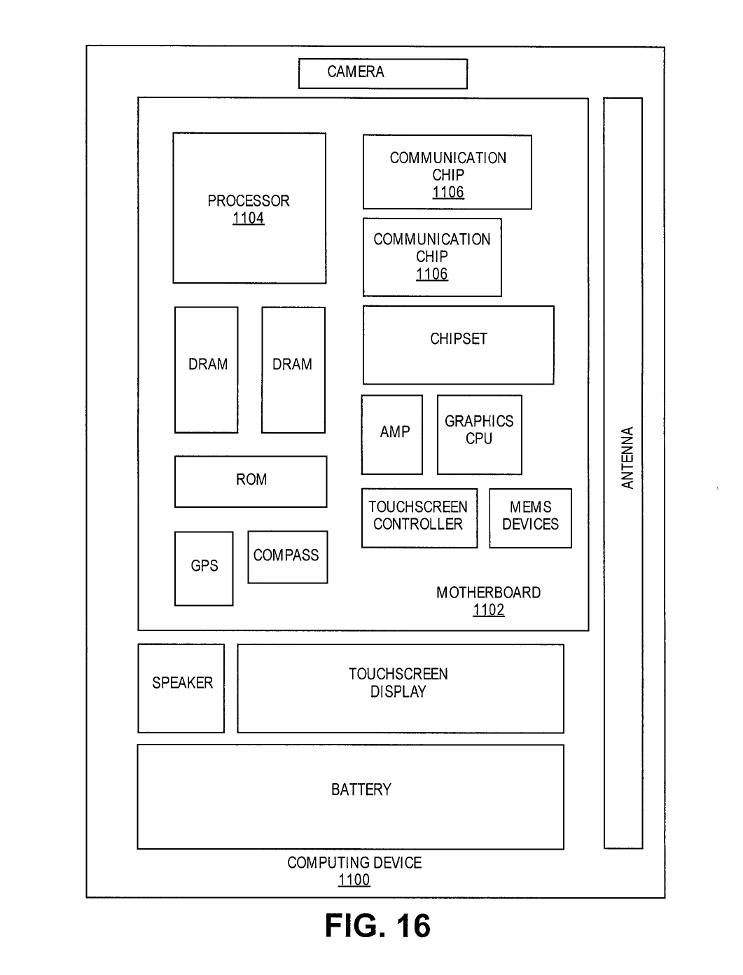

FIG. 16 illustrates computing device 1100 in accordance with one implementation. Computing device 1100 houses board 1102. Board 1102 may include a number of components, including but not limited to processor 1104 and at least one communication chip 1106. Processor 1104 is physically and electrically coupled to board 1102. In some implementations at least one communication chip 1106 is also physically and electrically coupled to board 1102. In further implementations, communication chip 1106 is part of processor 1104.

Depending on its applications, computing device 1100 may include other components that may or may not be physically and electrically coupled to board 1102. These other components include, but are not limited to, volatile memory (e.g., DRAM), non-volatile memory (e.g., ROM), micro-electromechanical systems (MEMS) devices (e.g., sensors, actuators), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 1106 enables wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 1106 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 1100 may include a plurality of communication chips 1106. For instance, first communication chip 1106 may be dedicated to shorter range wireless communications such as Wi-Fi and Bluetooth and second communication chip 1106 may be dedicated to longer range wireless communications such as GPS, EDGE, GPRS, CDMA, WiMAX, LTE, Ev-DO, and others.

Processor 1104 of computing device 1100 includes an integrated circuit die packaged within processor 1104. In some implementations, the integrated circuit die of the processor includes one or more devices, such as transistors or metal interconnects. The term “processor” may refer to any device or portion of a device that processes electronic data from registers and/or memory to transform that electronic data into other electronic data that may be stored in registers and/or memory.

Communication chip 1106 also includes an integrated circuit die packaged within communication chip 1106. In accordance with another implementation, the integrated circuit die of the communication chip includes one or more devices, such as transistors or metal interconnects.

In further implementations, another component housed within computing device 1100 may contain an integrated circuit die that includes one or more devices, such as transistors or metal interconnects.

In various implementations, computing device 1100 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, a digital video recorder, or a hybrid device. In further implementations, computing device 1100 may be any other electronic device that processes data.

### EXAMPLES

Example 1 is an apparatus including a package comprising a die and a package substrate, the package substrate including a conductor; and a stiffener body electrically coupled to the conductor of the package substrate.

In Example 2, the apparatus of Example 1 further includes a conductive material between the stiffener body and the conductor of the package substrate.

In Example 3, the conductive material in the apparatus of Example 2 includes a conductive adhesive.

In Example 4, the conductive material in the apparatus of Example 2 includes a solder paste or micro balls.

In Example 5, the conductive material in the apparatus of Example 2 includes conductive material coated microballs.

In Example 6, the conductive material in the apparatus of Example 2 includes a layer of continuous material between the stiffener body and the conductor of the package substrate.

In Example 7, the stiffener body in the apparatus of Example 1 includes a generally planar surface and a plurality of protrusions extending from the generally planar surface, wherein the plurality of protrusions are coupled to the conductor of the package substrate.

In Example 8, the apparatus of Example 1 further includes an electrically conductive material disposed on the stiffener and the package substrate, the electrically conductive material electrically coupling the stiffener body to the conductor of the package substrate.

In Example 9, the package substrate in the apparatus of Example 8 includes a plurality of conductive layers each defining a conductor, and the electrically conductive material is coupled to at least one of the plurality of conductive layers.

In Example 10, the package substrate in the apparatus of Example 9 includes a pair of opposing side portions defining a thickness and the electrically conductive material is disposed on the pair of opposing side portions.

In Example 11, the plurality of conductive layers in the apparatus of Example 9 include an initial layer positioned closest to the stiffener and an ultimate layer positioned furtherest from the stiffener, wherein the electrically conductive material is coupled to one of the plurality of conductive layers other than the initial layer.

Example 12 is an apparatus including a package including a die and a package substrate; a stiffener body coupled to the package substrate; and an electrically conductive path between the stiffener body and the package substrate.

In Example 13, the electrically conductive path in the apparatus of Example 12 includes a conductive material between the stiffener body and the conductor of the package substrate.

In Example 14, the conductive material in the apparatus of Example 13 includes a conductive adhesive.

In Example 15, the conductive material in the apparatus of Example 13 includes a solder paste or micro balls.

In Example 16, the conductive material in the apparatus of Example 13 includes conductive material coated microballs

In Example 17, the conductive material in the apparatus of Example 13 includes a layer of continuous material between the stiffener body and the conductor of the package substrate.

In Example 18, the stiffener body in the apparatus of Example 12 includes a generally planar surface and a plurality of protrusions extending from the generally planar surface, wherein the plurality of protrusions include the electrically conductive path between the stiffener and the package substrate.

In Example 19, the apparatus of Example 12 further includes an electrically conductive material disposed on the stiffener and the package substrate, wherein the electrically conductive material includes the electrically conductive path between the stiffener and the package substrate.

In Example 20, the package substrate in the apparatus of Example 19 includes a plurality of conductive layers each defining a conductor, and the electrically conductive material is coupled to at least one of the plurality of conductive layers.

In Example 21, the package substrate in the apparatus of Example 20 includes a pair of opposing side portions defining a thickness and the electrically conductive material is disposed on the pair of opposing side portions.

In Example 22, the plurality of conductive layers in the apparatus of Example 20 include an initial layer positioned closest to the stiffener and an ultimate layer positioned furtherest from the stiffener, wherein the electrically conductive material is coupled to one of the plurality of conductive layers other than the initial layer.

Example 23 is a method including electrically coupling a stiffener body to a conductor of a package substrate.

In Example 24, electrically coupling the stiffener body to the conductor in the method of Example 23 includes forming a conductive material between the stiffener body and the conductor of the package substrate.

In Example 25, the conductive material in the method of Example 24 includes a layer.

In Example 26, the the stiffener body in the method of Example 23 includes a generally planar surface and a plurality of protrusions extending from the generally planar surface, wherein electrically coupling the stiffener body to the conductor includes contacting the conductor with the plurality of protrusions.

In Example 27, electrically coupling the stiffener body to the conductor in the method of Example 23 includes forming a conductive material on the stiffener body and the package substrate.

In Example 28, the conductor in the method of Example 23 is designated a ground such that the coupling of the stiffener body to the conductor mitigates electromagnetic interference.

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1.-22. (canceled)

23. A method comprising:
electrically coupling a stiffener body to a conductor of a package substrate, the stiffener comprising a shape of a frame and surrounding a die coupled to the package substrate.

24. The method of claim 23, wherein electrically coupling the stiffener to the conductive layer comprises forming a conductive material between the stiffener and the conductive layer of the package substrate.

25. The method of claim 24, wherein the conductive material comprises a layer.

26. The method of claim 23, wherein stiffener comprises a generally planar surface and a plurality of protrusions extending from the generally planar surface, wherein electrically coupling the stiffener to the conductive layer comprises contacting the conductive layer with the plurality of protrusions.

27. The method of claim 23, wherein electrically coupling the stiffener to the conductive layer comprises forming a conductive material on the stiffener and the package substrate.

28. The method of claim 23, wherein the conductive layer is designated a ground such that the coupling of the stiffener to the conductive layer mitigates electromagnetic interference.

29. The method of claim 23, wherein the stiffener comprises a non-conductive material.

30. The method of claim 29, further comprising introducing a conductive shield layer on the stiffener.

31. The method of claim 30, further comprising introducing the conductive shield layer on the package substrate.

32. The method of claim 31, wherein the conductive shield layer is introduced by a sputtering process.
